(19) United States
(12) Patent Application Publication
(10) Pub. No.: US 2016/0161586 A1
(43) Pub. Date: Jun. 9, 2016

(54) System And Method For Radiation Biodosimetry On Nail Clippings Using Electron Paramagnetic Resonance Spectroscopy

(71) Applicant: The Trustees of Dartmouth College, Hanover, NH (US)

(72) Inventors: Harold M. Swartz, Lyme, NH (US); Steven G. Swarts, Archer, FL (US); Dmitriy Tipikin, Medford, MA (US); Dean Wilcox, Etna, NH (US); Xiaoming He, Hanover, NH (US); Thomas Matthews, Hanover, NH (US)

(21) Appl. No.: 15/012,720

(22) Filed: Feb. 1, 2016

Related U.S. Application Data
(63) Continuation-in-part of application No. 13/056,927, filed on Jan. 31, 2011, now abandoned.
Application No. 13/056,927 is a continuation-in-part of application No. 13/061,423, filed on Oct. 20, 2011, now Pat. No. 9,255,901.
(60) Provisional application No. 62/110,224, filed on Jan. 30, 2015.
(60) Provisional application No. 61/085,337, filed on Jul. 31, 2008.
(60) Provisional application No. 61/093,338, filed on Aug. 31, 2008.

(51) Int. Cl. G01R 33/60; G01R 33/30

(52) U.S. Cl. CPC G01R 33/60; G01R 33/30

(57) ABSTRACT

A system and method are disclosed for post-exposure radiation biodosimetry on subjects using electron paramagnetic resonance (EPR) spectroscopy of nail clippings from the subjects. Basis spectra averaged from a plurality of nail clipping measurements are used to spectrally decompose an EPR-measured signal and identify a radiation-induced signal (RIS). The RIS is used to determine an exposure dose from a standard curve. A collection apparatus provides for harvesting and storing nail clippings in a dry, oxygen-reduced, environment to prevent sample degradation. The collection apparatus includes a container with an atmosphere isolated from external atmosphere and a sample bag impermeable to oxygen and water vapor. The sample bag includes an oxygen absorber and a desiccant for storing nail clippings with minimal exposure to oxygen and water vapor, thereby retaining a stable EPR signal.

### RELATED APPLICATIONS

This application claims priority to U.S. Provisional Patent Application 62/110,224 filed 30 Jan. 2015. This application also is a continuation in part of U.S. patent application Ser. No. 13/056,927 filed Jan. 31, 2011, which is the national phase application of PCT Application Number PCT/US2009/052261 filed Jul. 30, 2009, which claims priority to U.S. Provisional Application No. 61/085,337 filed Jul. 31, 2008, all of which are incorporated herein by reference.

This application also is a continuation in part of U.S. patent application Ser. No. 13/061,423 filed Oct. 20, 2011, which in turn claims priority to PCT Application Number PCT/US2009/055414 filed Aug. 28, 2009, which in turn claims priority to U.S. Provisional Application No. 61/093,338 filed Aug. 31, 2008, all of which are incorporated herein by reference.

### U.S. GOVERNMENT RIGHTS

This invention was made with government support under U19AI091173 awarded by the National Institute of Health. The government has certain rights in the invention

### BACKGROUND

Ionizing radiation causes hydroxyapatite in tooth enamel and keratin structures, such as fingernails, to generate stable unpaired electrons. These unpaired electrons may be measured using a technique known as Electron Paramagnetic Resonance (EPR) Spectroscopy, or Electron Spin Resonance Spectroscopy. EPR Spectroscopy includes three fundamental steps. The first step aligns the spins of any unpaired electrons in a substance with a magnetic field. The second step perturbs the aligned spins with radio-frequency electromagnetic radiation at and near a resonant frequency. The third step measures the resulting absorption spectrum. An EPR signal may be acquired by sweeping the intensity of the magnetic field and holding the electromagnetic frequency constant, or by holding the magnetic field intensity constant and sweeping the electromagnetic frequency, while making repeated measurements.

### SUMMARY OF THE INVENTION

In an embodiment, a method is provided for radiation biodosimetry on nail clippings using electron paramagnetic resonance (EPR) spectroscopy. The method includes receiving an EPR-measured signal from an EPR spectroscopy measurement of nail clippings, spectrally decomposing the EPR-measured signal to identify a radiation-induced signal (RIS) of the EPR-measured signal, subtracting a background signal from the RIS to generate a background-subtracted RIS, and determining an exposure dose from the background-subtracted RIS.

In an embodiment, a system is provided for radiation biodosimetry on a nail clipping of a subject using electron paramagnetic resonance (EPR) spectroscopy. The system includes an EPR spectrometer with a High-Q resonator configured to perform EPR spectroscopy on the nail clipping. The system further includes a computer having in a memory system software configured to spectrally decompose the EPR-measured signal, to subtract a background signal from the radiation-induced signal (RIS) portion of the EPR-measured signal, and to determine an exposure dose from the background-subtracted RIS according to a set of instructions.

A software product is disclosed comprising instructions, stored on computer-readable media, wherein the instructions, when executed by a computer, perform steps for spectral decomposition of an EPR signal from at least one nail clipping. The instructions for spectral decomposition include fitting the EPR signal to mechanically-induced signal (MIS) composite basis spectra and a radiation-induced signal (RIS) basis spectrum, and determining the magnitude of a MIS component and a RIS component of the EPR signal from comparison with respective basis spectra.

In an embodiment, a system provides radiation biodosimetry on nail clippings using electron paramagnetic resonance (EPR) spectroscopy. The system includes a sample bag impermeable to oxygen and water vapor that is heated sealed to ensure an airtight seal. An oxygen absorber located inside the sample bag is configured to absorb oxygen, and a desiccant located inside the sample bag is configured to absorb water vapor. Nail clippings stored inside the sample bag have minimal exposure to oxygen and water vapor, thereby retaining a stable EPR signal.

### BRIEF DESCRIPTION OF THE FIGURES

FIG. 1 is a block diagram showing a system for radiation biodosimetry on nail clippings using electron paramagnetic resonance (EPR) spectroscopy, in an embodiment.

FIG. 2 is a schematic drawing of a collection apparatus used to harvest and store nail clippings, according to an embodiment.

FIG. 3 is a block diagram showing steps of one method for radiation biodosimetry on nail clippings using electron paramagnetic resonance spectroscopy, in an embodiment.

FIG. 4 is a block diagram showing steps of one method for harvesting nail clippings, according to an embodiment.

FIG. 5 is a block diagram showing steps of one method to spectrally decompose a measured EPR signal, according to an embodiment.

FIG. 6 is a block diagram illustrating steps of determining a MIS and RIS basis spectra, according to an embodiment.

FIG. 7 is a block diagram showing steps of a method used to determine an exposure dose from an EPR measurement, according to an embodiment.

FIG. 8 shows three mechanically-induced signal (MIS) spectral components caused by cutting nail clippings.

FIG. 9 shows amplitudes of two MIS spectral components plotted against one another from a plurality of measurements.

FIG. 10 shows amplitudes of two MIS spectral components plotted against one another from a plurality of measurements.

### DETAILED DESCRIPTION OF THE EMBODIMENTS

The present invention uses finger or toe nail clippings to measure past exposure of a subject to ionizing radiation. EPR spectroscopy has previously been used to accurately quantify exposure to ionizing radiation using teeth or bone. Systems and methods disclosed below accurately quantify radiation exposure using nail clippings. Such systems and methods enable screening of individuals following a nuclear disaster, or other radiation producing event, to help determine appropriate medical treatment. No such screening occurs in the prior art.

Accurate quantification of radiation exposure using nail clippings is difficult, partly due to the fact that cutting a nail generates an EPR signal, known as a mechanically-induced signal (MIS), which overlaps with a radiation-induced signal (RIS) of interest. Furthermore, the MIS and RIS spectral components differ with time after cutting and irradiation, respectively. The signal stabilities depend on the water and oxygen content of the nail and the ambient temperature. Water content of nail clippings influences stability of the MIS- and RIS-component signals, and reducing water content in nails increases the stability of spectral components in an irradiated clipped nail. Oxygen content is important in MIS signal decay, and storing nail clippings in an inert gas reduces the oxygen content, thereby minimizing signal loss. By reducing both water and oxygen content after harvesting, the intensities of the MIS and RIS components in the nail clippings may be retained. A collection apparatus disclosed herein was developed; the apparatus provides for nail harvesting and storage in an atmosphere substantially without water and oxygen to control stability of MIS and RIS signal components.

Three key features help enable accurate quantification of past radiation exposure using nail clippings. First, the collection apparatus permits harvesting and storing of nail clippings to control EPR signal stabilities, thus minimizing sample variability. Second, a spectral decomposition algorithm was developed using a basis EPR spectrum from detailed studies of EPR spectral properties. Third, a nail polish removal solution was developed to remove contaminating nail polish without interfering with EPR spectroscopy measurements.

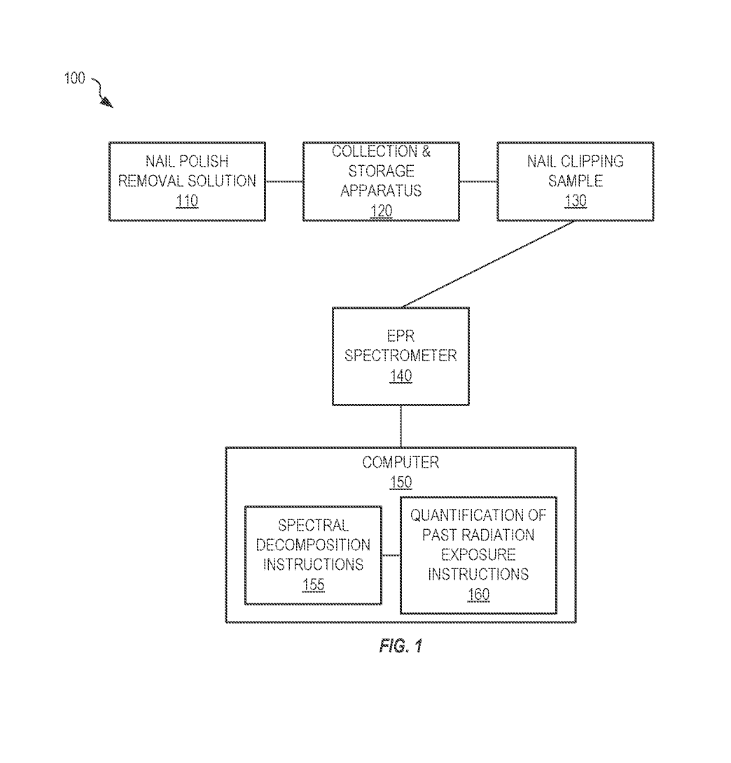

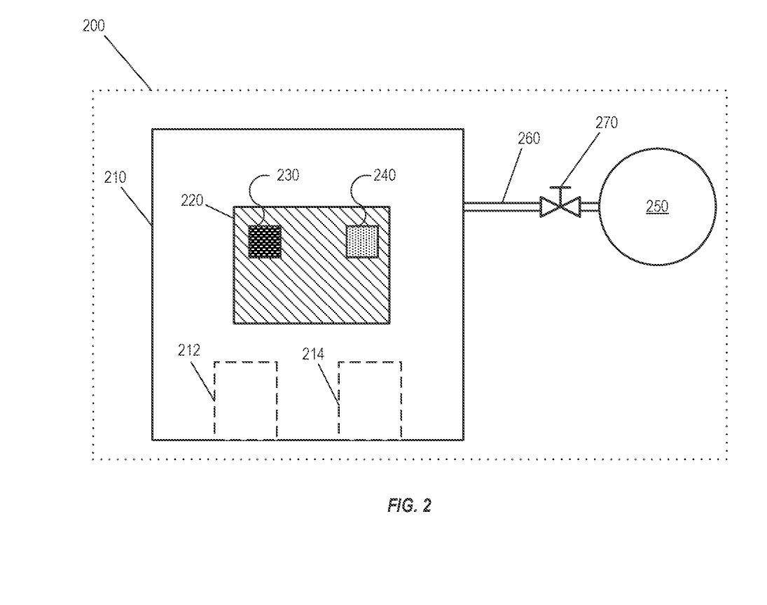

In particular, FIG. 1 is a block diagram showing a system 100 for radiation biodosimetry on nail clippings using electron paramagnetic resonance (EPR) spectroscopy. System 100 includes a nail polish removal solution 110 optimized to minimize interference with the EPR spectroscopy. In an embodiment, the nail polish removal solution 110 is a chemical solution that consists of four volumes of acetone and one volume of butyl acetate. A collection apparatus 120 includes a container with an inert gas atmosphere and a sample bag with a desiccant and an oxygen absorber (shown in detail in FIG. 2). A nail clipping sample 130 includes one or more nail clippings with polish removed, using removal solution 110, and which were harvested and stored in collection apparatus 120. This can also include nail clippings with polish remaining that will have polish removed using removal solution 110 at time of analysis. In an embodiment, nail clipping sample 130 includes all clippings from one limb of an individual.

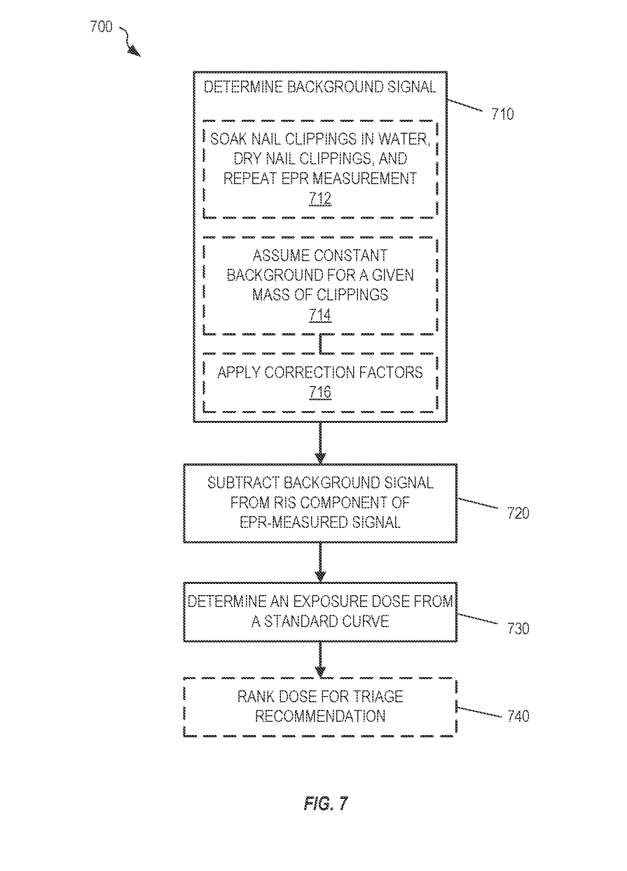

EPR measurements of nail clipping sample 130 are made using an EPR spectrometer 140. EPR spectrometer 140 is for example a Bruker EMX X-band EPR spectrometer with a High-Q resonator. Spectrometer 140 produces absorption spectra that require spectral decomposition, such as through software (shown as spectral decomposition instructions 155 executed by a computer 150). Following processing of spectral decomposition instructions 155, quantification of past radiation exposure is determined, such as through machine readable code (shown as quantification of past radiation exposure instructions 160, executed by computer 150). Quantification of past radiation exposure instructions 160 are shown in detail in FIG. 7.

FIG. 2 is a schematic drawing of one exemplary collection and storage apparatus 200 used to harvest and store nail clippings for radiation biodosimetry using EPR spectroscopy. Collection apparatus 200 is an example of collection apparatus 120 of FIG. 1. A container 210 may include optional glove inserts for a left hand 212 and right hand 214, which allow a user to reach inside container 210 with one or two hands while maintaining a substantially isolated atmosphere inside container 210. Examples of containers include, but are not limited to, glove bags, chemical hoods, boxes, tents, and entire rooms or buildings, so long as they are capable of maintaining a substantially isolated atmosphere. At least one sample bag 220 is placed inside container 210; the sample bag is made of material impermeable to oxygen and water vapor to isolate samples from them, which helps to retain stable EPR signals in nail clippings. Sample bag 220 is for example made of mylar and may include an interlocking zipper to produce an airtight seal (alternatively sample bag 220 is heat-sealed to ensure an airtight seal). In an embodiment, the sample bag includes an oxygen absorber 230 to absorb oxygen and a desiccant 240 to absorb water vapor. Oxygen absorber 230 may be an iron-based or a non-ferrous oxygen scavenger. The iron-based oxygen scavenger may be an iron-based powder that includes sodium chloride to act as a catalyst. Desiccant 240 may be a zeolite molecular sieve.

A source 250 of dry inert gas is connected to container 210 via a pathway 260. Pathway 260 may be a tube, hose, or pipe, or any suitable conduit for gas flow. A valve 270 enables opening and closing of inert gas source 250. Valve 270 is for example depicted in FIG. 2 as a screw-down valve, but it is to be understood that valve 270 may be of any type used to open and close inert gas source 250 and is thus not limited to a screw-down valve. Valve 270 and pathway 260 enable transfer of the inert gas from source 250 to container 210. Pathway 260 mechanically connects source 250 to container 210. Likewise, when valve 270 is open, inert gas in source 250 is in communication with the atmosphere inside container 210 via pathway 260. In an embodiment, inert gas source 250 has an internal pressure greater than one atmosphere. Therefore, when valve 270 is open, inert gas flows from high pressure source 250 through pathway 260 into container 210 filling it with inert gas. Inert gas helps retain stable EPR signals in nail clippings because it is free of oxygen and water vapor. The inert gas in source 250 is for example dry nitrogen gas. Dry nitrogen gas is a preferred inert gas because it is inexpensive and readily available.

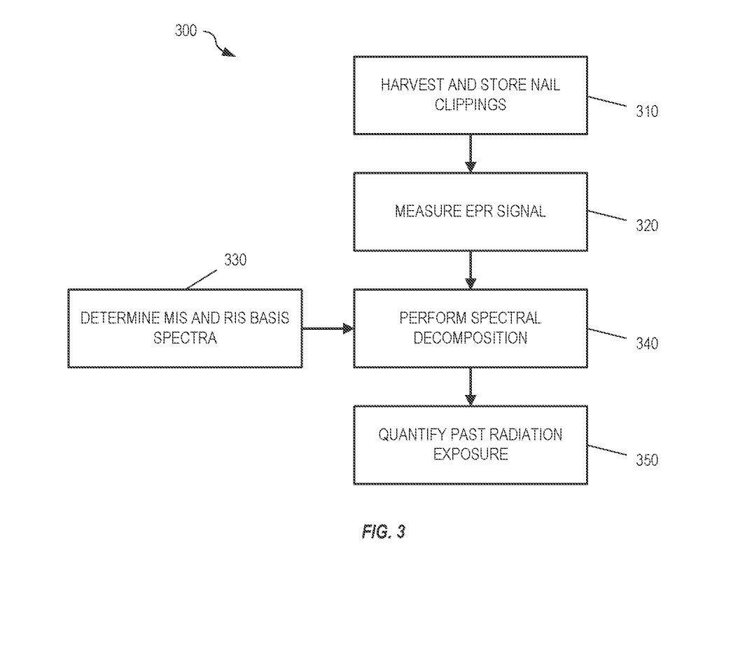

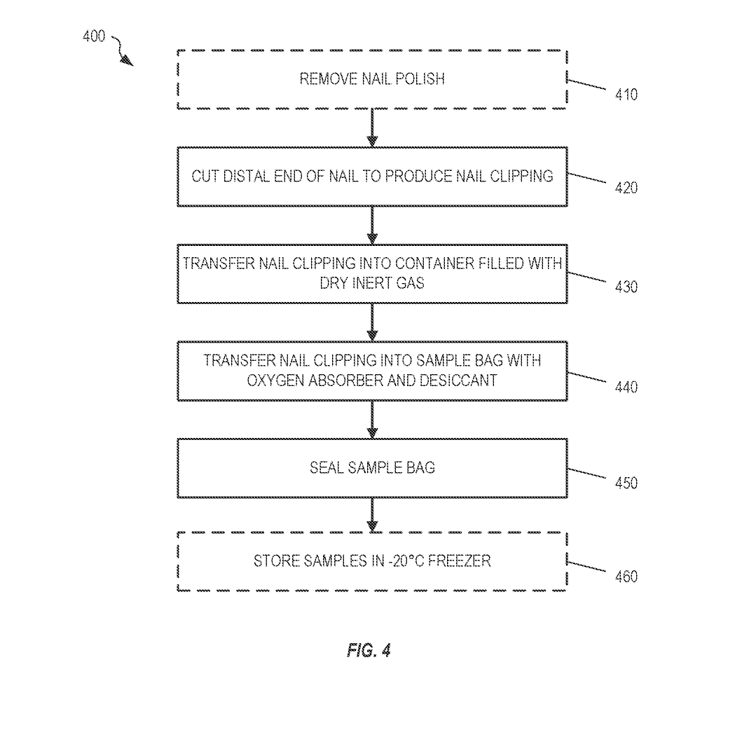

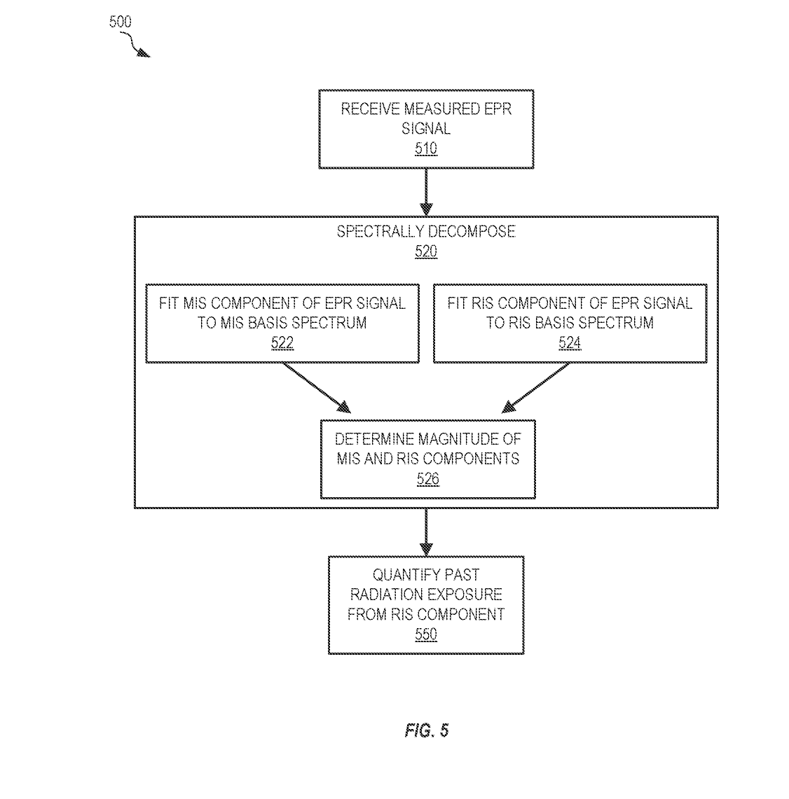

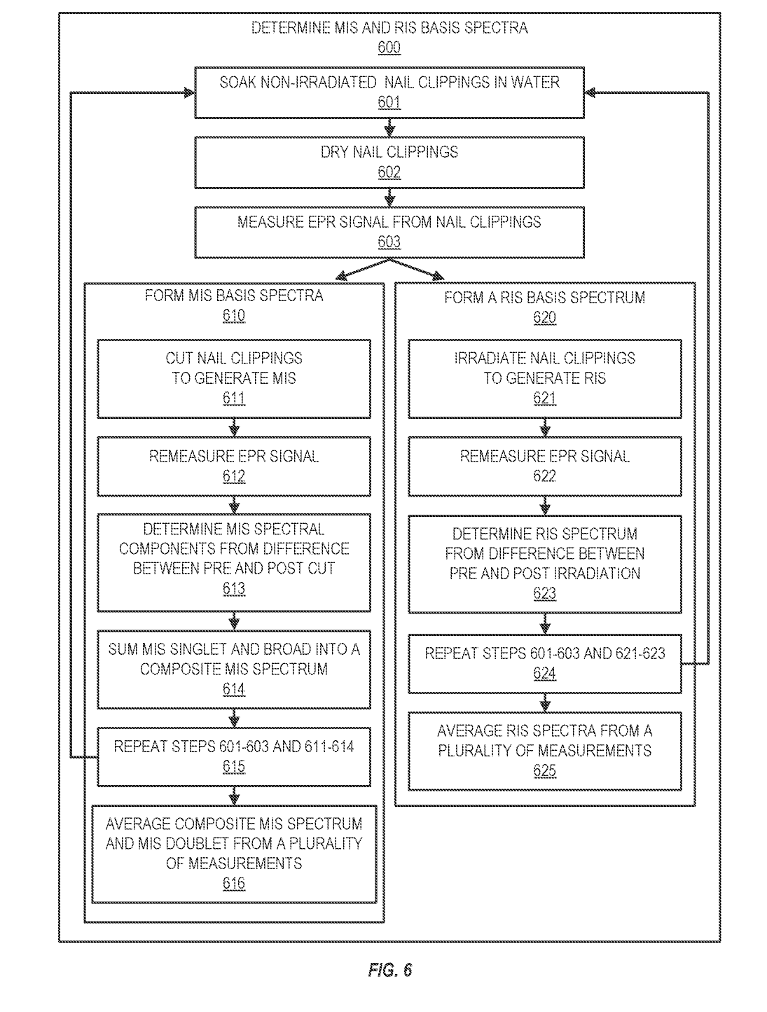

FIG. 3 is a block diagram showing steps of one method for radiation biodosimetry on nail clippings using electron paramagnetic resonance spectroscopy. A step 310 (shown in detail in FIG. 4) harvests nail clippings and stores the clippings to reduce sample degradation and variability. In an example of step 310, nail polish is removed using removal solution 110 and nails are harvested and stored in collection & storage apparatus 120 of FIG. 1. Alternatively, nail polish is removed with removal solution 110 following nail harvesting. A step 320 measures EPR signals of nail clippings of step 310. In an example of step 320, EPR spectrometer 140 of FIG. 1 is used. Its center field of the magnet is set at 3500 gauss and its sweep width is set to 150 gauss. The modulation frequency is 100 kHz with amplitude of five gauss. The microwave incident power is 0.4 mW. Signals are acquired as the average of five scans using a time constant of 40.96 ms and sweep time of 40 s. Alternatively, shorter sweep times are used with an increased number of scans for averaging to improve signal to noise ratio. The amplitude of each nail spectrum is normalized both to the signal of a reference standard (single peak at g=1.98 from a standard supplied by Bruker BioSpin, Bilerica, Mass., USA), and to nail mass. A step 330 determines MIS and RIS basis spectra (shown in detail in FIG. 6). The MIS and RIS basis spectra are for example determined in advance to provide a reference for measurements of many nail clipping samples. A step 340 performs a spectral decomposition of the EPR signal from step 320. Step 340 uses the MIS and RIS basis spectra of step 330 to determine a MIS component and a RIS component of the EPR signal. In an example of step 340, spectral decomposition instructions 155 are executed by machine readable code on a computer 150 of FIG. 1 (shown in more detail in FIG. 5) to obtain the MIS and RIS components. A step 350 accurately quantifies past radiation exposure using a spectral decomposition result of step 340. In an example of step 350, quantification of past radiation exposure instructions 160 are executed by machine readable code, which may comprise software or firmware, on a computer 150 of FIG. 1 (shown in more detail in FIG. 7) to determine past radiation exposure.

FIG. 4 is a block diagram showing steps of one exemplary method 400 for harvesting nail clippings from a subject for radiation biodosimetry using electron paramagnetic resonance (EPR) spectroscopy. Method 400 is an example of step 310 of FIG. 3. An optional step 410 removes any nail polish or hardener on the subject's nails with removal solution 110 of FIG. 1, which is a specially designed solution formulated for compatibility with EPR measurements. Step 410 is optional because not all nails contain polish or hardener, but any nail polish or hardener must be removed to prevent interference with EPR spectroscopy measurements. The removal of polish can occur before nail clippings are harvested as in step 310 or removed from the nail clipping prior to analysis in step 320. A step 420 cuts a portion of a distal end of a nail from a finger or toe of the subject to produce a nail clipping. The nail clipping may be cut using conventional nail clippers or scissors. Very sharp scissors are for example used and an entire nail clipping is removed as a single piece. However, cutting a single piece may not be practical, and a plurality of pieces may result due to the brittleness of the nails, a short distal extension of the nail from the nail bed, or the cutting method. A nail clipping is thus generally one or more pieces of nail cut from a single finger or toe. A step 430 transfers the nail clipping into container 210 of FIG. 2 using forceps. Container 210 is filled with a dry inert gas from source 250 via pathway 260 of FIG. 2. Step 440 transfers the nail clipping into sample bag 220 located inside container 210 of FIG. 2. Step 440 is performed inside container 210 to minimize exposure of the atmosphere inside sample bag 220 to oxygen and water vapor. All nail clippings from one limb of a subject may be combined in one sample bag 220 to form one nail clipping sample 130 of FIG. 1. A step 450 seals the sample bag 220 with an airtight seal, such as by using an interlocking zipper or heated seal. An optional step 460 stores the samples, located in sealed sample bags 220, in a −20° C. freezer. Step 460 is optional because in some embodiments the samples may not need to be stored because they are measured immediately using EPR spectroscopy. Collection apparatus 200 combined with method 400 enables harvesting and storing nail clippings to reduce exposure to oxygen and water vapor, thus reducing signal degradation in sample and variability.

FIG. 5 is a block diagram showing steps of one exemplary method 500 for performing a spectral decomposition. Method 500 is an example of step 340 of FIG. 3 and is 155 of FIG. 1. A step 510 receives a measured EPR signal from EPR spectrometer 140 of FIG. 1. A step 520 spectrally decomposes the EPR signal received in step 510. A step 522 fits the MIS component of the EPR signal to MIS basis spectra, such as an MIS basis spectrum determined according to FIG. 6. A step 524 fits a RIS component of the EPR signal to a RIS basis spectrum, such as an RIS basis spectrum determined according to FIG. 6. In an embodiment, such a fit between the component signals and basis spectra include a linear least-squares fit, thereby minimizing differences between the component signals and the basis spectra. Steps for determining the MIS and RIS basis spectra are illustratively shown in FIG. 6. A step 526 determines the magnitude of the MIS and RIS components of the EPR signal based on the fit with respective basis spectra. A step 550 quantifies past radiation exposure from the RIS component of the EPR signal. Step 550 is an example of step 350 of FIG. 3, and is shown in detail in FIG. 7.

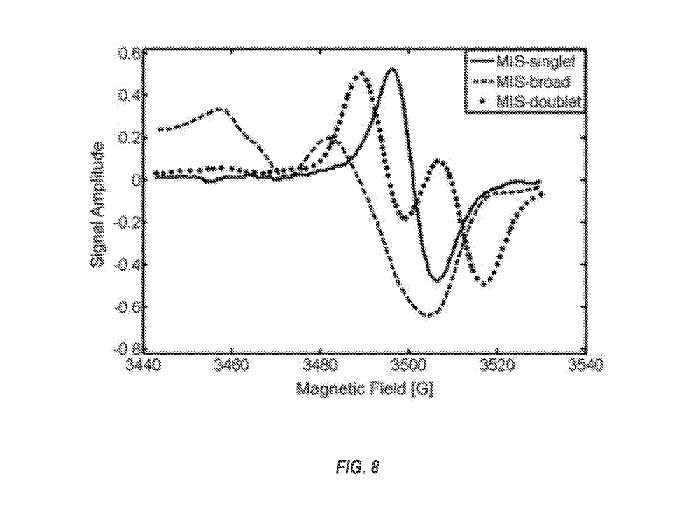

FIG. 6 is a block diagram illustrating steps of determining MIS and RIS basis spectra, which is an example of step 330 of FIG. 3. The MIS and RIS basis spectra are used by spectral decomposition instructions 155 executed by computer 150 of FIG. 1, in an embodiment. A step 601 soaks non-irradiated nail clippings in water to remove any MIS and RIS. In an example of step 601, the nail clippings are soaked in water for fifteen minutes. A step 602 dries the nail clippings. In an example of step 602, the nail clippings are dried for thirty to sixty minutes under dry air or inert gas. A step 603 measures the EPR signal of the nail clippings. In an example of step 603, the EPR signal is measured using EPR spectrometer 140 of FIG. 1. A step 610, which includes steps 611 to 616, forms MIS basis spectra. A step 611 cuts the nail clippings into smaller pieces to generate a MIS. A step 612 remeasures the EPR signal of the nail clippings using EPR spectrometer 140 of FIG. 1. A step 613 determines three individual MIS spectral components from the difference between pre- and post-cut EPR signals. Individual MIS spectral components include a MIS singlet, a MIS doublet, and a MIS broad, which are shown in FIG. 8 and described in detail below. A step 614 sums the MIS singlet and MIS broad to form a composite MIS spectrum of these two spectral components, with a MIS doublet spectrum remaining separate. A step 615 repeats steps 601 to 603 and 611 to 614 using a plurality of nail clipping samples. A step 616 averages the composite MIS spectrum and separate MIS doublet from a plurality of measurements to form an MIS basis spectrum. In an example of step 616, composite MIS from sixty nail clipping measurements are averaged to form the MIS basis spectrum. Following steps 601, 602, and 603, a step 620 forms a RIS basis spectrum that includes steps 621 to 625. A step 621 irradiates nail clippings to generate a RIS. In an example of step 621, nail clipping samples are exposed to a ¹³⁷Cesium source. A step 622 remeasures EPR signals of the nail clippings using EPR spectrometer 140 of FIG. 1. A step 623 determines a RIS from the difference between pre- and post-irradiated spectra. A step 624 repeats steps 601 to 603 and 621 to 623 using a plurality of nail clipping samples. A step 625 averages the RIS acquired from a plurality of measurements. In an example of step 625, RIS from sixty nail clipping measurements are averaged to form the RIS basis spectrum. In an embodiment, the RIS basis spectrum is approximated by a first derivative of a Lorentzian function.

FIG. 7 is a block diagram showing steps of one exemplary method 700 used to accurately quantify past radiation exposure of at least one nail clipping. Method 700 is an example of step 350 of FIG. 3 and step 550 of FIG. 5. Underlying the MIS and RIS components of an EPR signal is an inherent background signal. The background signal and RIS overlap and have similar power saturation properties. Therefore, spectral decomposition cannot separate these two spectral components and an additional step is used to separate the RIS from the background signal. As shown in FIG. 7, a step 710 determines the background signal. In one embodiment of step 710, an optional step 712 determines the background signal by soaking nail clippings in water to remove the MIS and RIS, drying the clippings, and immediately repeating an EPR measurement using EPR spectrometer 140 of FIG. 1. In an example of step 712, the nail clippings are soaked in water for fifteen minutes and dried for thirty to sixty minutes under air or inert gas.

Soaking the nail clippings in water returns the original physical state (removing the MIS and RIS), but the background signal remains and slowly increases over a period of several days to a maximum value. This “rebound” in the background signal is greatly reduced by keeping the clipped nails in dry inert gas. Thus, the background signal intensity can be controlled to minimize variability by following method 400 to store nail clipping sample 130 of FIG. 1 in sample bag 220, containing oxygen absorber 230 and desiccant 240, of FIG. 2. In an alternate embodiment of step 710, an optional step 714 assumes a constant background signal for a given mass of clippings; such an assumption is based on the low variability in the background amplitude observed in nail clippings when collection apparatus 200 and method 400 are used to harvest and store nail clippings. In an embodiment of step 710, an optional step 716 applies correction factors to the constant background signal of step 714 to account for differences in gender, ethnicity or past exposure of the subject to ultraviolet light. A step 720 subtracts the background signal from the RIS component of the EPR-measured signal to generate a background-subtracted RIS. In an example of step 720, subtraction of the background signal is performed by quantification of past radiation exposure instructions 160 on computer 150 of FIG. 1. A step 730 determines an exposure dose for the subject. In an example of step 730, the background-subtracted RIS is compared to a standard curve of nail clippings exposed to known radiation doses by quantification of past radiation exposure instructions 160 executed by computer 150 of FIG. 1. The standard curve is generated by exposing a series of nail clipping samples to a series of increasing radiation doses. The standard curve may be generated from replicate nail clipping samples exposed to doses of zero, one, two, four, or six Gy using a ¹³⁷Cesium source, for example. Optional step 740 ranks a measured exposure dose and compares it to triage limits in order to provide a recommendation for appropriate medical care. In an example of optional step 740, the recommendation is determined by quantification of past radiation exposure instructions 160 executed by computer 150 of FIG. 1.

FIG. 8 shows three individual MIS spectral components caused by cutting nail clippings. The three MIS spectral components include for a particular wavelength the following: 1) a spectrum denoted as MIS-doublet with two distinct peaks approximately eighteen gauss apart; 2) an anisotropic spectrum covering one-hundred fifty gauss, denoted as MIS-broad; and, 3) a spectrum with a single distinct peak, known as a singlet, with a ten gauss line width, denoted as MIS-singlet. Underlying these three spectral components is a background signal, which has a single peak coincident with the MIS-singlet.

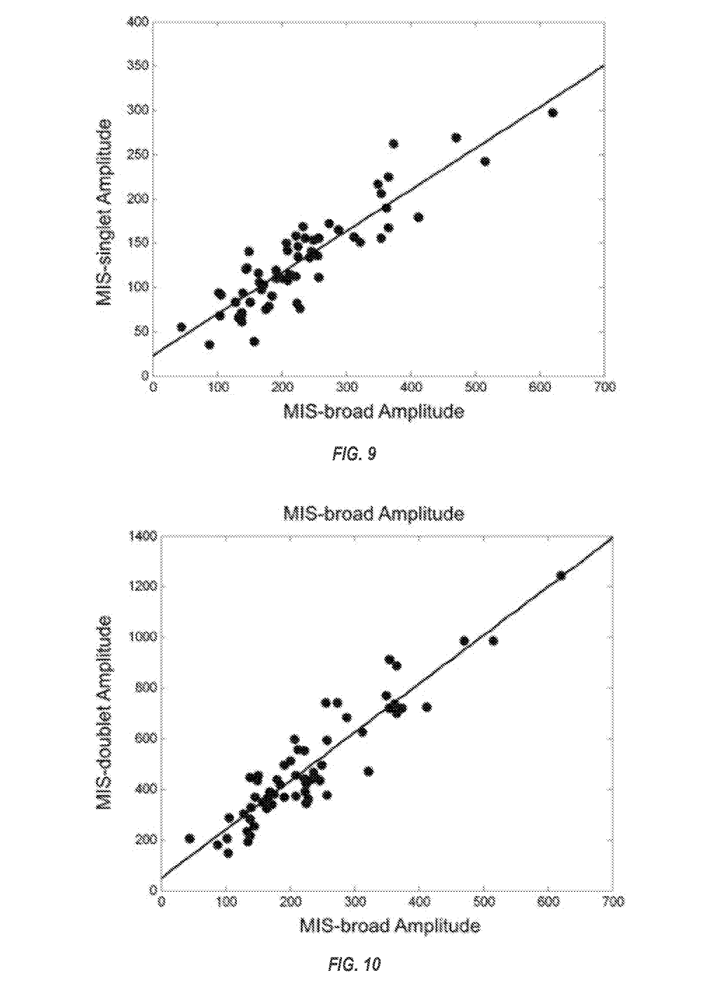

FIGS. 9 and 10 show data collected from EPR-measurements of non-irradiated nail clippings using collection apparatus 200 combined with method 400. The data provide a good correlation between the three MIS spectral components, as shown in FIGS. 9 and 10, indicating a stable intensity ratio of the MIS-broad and MIS-singlet spectra and reduction in the decay rate of the MIS-doublet. Stabilization of the MIS spectral components is helpful to formation of the basis spectrum that includes all three MIS components.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A method for radiation biodosimetry on at least one nail clipping of a subject using electron paramagnetic resonance (EPR) spectroscopy, comprising:
receiving an EPR-measured spectrographic signal from an EPR spectroscopy measurement of the nail clipping;
spectrally decomposing the EPR-measured spectrographic signal, thereby identifying a radiation-induced signal (RIS) component of the EPR-measured signal and separating the RIS from a mechanically-induced (MIS) signal component of the EPR-measured spectrographic signal; and
subtracting a background signal from the RIS, thereby generating a background-subtracted RIS; and
determining exposure dose from the background-subtracted RIS.

2. The method of claim 1, the step of spectrally decomposing the EPR-measured signal comprising:
determining mechanically-induced signal (MIS) basis spectra;
determining a RIS basis spectrum;
fitting a MIS component of the EPR-measured signal to MIS basis spectra and a RIS component of the EPR-measured signal to the RIS basis spectrum, thereby determining magnitude of the MIS and RIS components.

3. The method of claim 1, further comprising ranking the exposure dose according to triage categories and, thereby triaging the subject for appropriate medical care.

4. A system for radiation biodosimetry on a nail clipping of a subject using electron paramagnetic resonance (EPR) spectroscopy, comprising:
an EPR spectrometer with a High-Q resonator configured to perform EPR spectroscopy on the nail clipping; and
a computer having in a memory system machine readable code configured to spectrally decompose the EPR-measured signal, to subtract a background signal from the radiation-induced signal (RIS) portion of the EPR-measured signal, and to determine an exposure dose from the background-subtracted RIS according to a set of instructions.

5. A software product comprising machine readable code stored on computer-readable media, wherein the machine readable code, when executed by a computer, perform steps for spectral decomposition of an EPR signal from at least one nail clipping, comprising:
fitting the EPR signal to mechanically-induced signal (MIS) basis spectra and a radiation-induced signal (RIS) basis spectrum; and
determining a magnitude of a MIS component and a magnitude of a RIS component of the EPR signal from comparison with the respective basis spectra.

6. The software product of claim 5, the step of fitting the EPR signal to a MIS basis spectrum comprising:
forming MIS basis spectra by
(a) determining three individual MIS spectral components measured before and after cutting nail clippings;
(b) summing at least two of the three MIS spectral components thereby forming a composite MIS spectrum; and
(c) averaging the composite MIS or individual component spectra from a plurality of nail clipping measurements.

7. The software product of claim 5, the step of fitting the EPR signal to a RIS basis spectrum, comprising:
forming a RIS basis spectrum by
(a) determining difference in EPR signals from nail clippings measured before and after radiation exposure, thereby distinguishing RIS from background; and
(b) averaging the RIS from a plurality of nail clipping measurements made before and after radiation exposure.

8. The software product of claim 5, the instructions further comprising:
subtracting a background signal from the RIS component to generate a background-subtracted RIS; and
determining an exposure dose by comparing the background-subtracted RIS to a standard curve of known exposures.

9. A system for harvesting at least one nail clipping for radiation biodosimetry thereon using electron paramagnetic resonance (EPR) spectroscopy, comprising:
a sample bag being impermeable to oxygen and water vapor, wherein the sample bag is heat-sealed to ensure an airtight seal;
an oxygen absorber located inside the sample bag configured to absorb oxygen; and
a desiccant located inside the sample bag configured to absorb water vapor,
wherein the at least one nail clipping is stored inside the sample bag to minimize exposure to oxygen and water vapor.

10. The system of claim 9, further comprising a sealable container adapted to contain an inert gas, wherein the sample bag is stored inside the sealed container thereby further isolating the at least one nail clipping from oxygen and water vapor.

11. The system of claim 9, further comprising a chemical solution, compatible with the EPR spectroscopy, adapted for removing nail polish from the nail clipping.

12. The system of claim 11, the chemical solution being optimized to minimize interference with the EPR spectroscopy.

13. The system of claim 9 further comprising:
an EPR spectrometer with a High-Q resonator configured to perform EPR spectroscopy on the at least one nail clipping; and
a computer having in a memory system machine readable code configured to spectrally decompose the EPR-measured signal, to subtract a background signal from the radiation-induced signal (RIS) portion of the EPR-measured signal, and to determine an exposure dose from the background-subtracted RIS according to a set of instructions.
